(19) United States
(12) Patent Application Publication
(10) Pub. No.: US 2025/0364437 A1
(43) Pub. Date: Nov. 27, 2025

(54) PROTECTION LAYER FOR SEMICONDUCTOR DEVICE

(71) Applicant: Taiwan Semiconductor Manufacturing Company, Ltd., Hsinchu (TW)

(72) Inventors: I-Han HUANG, New Taipei City (TW); Fu-Cheng CHANG, Hsinchu City (TW); Wen-Ting LAN, Hsinchu City (TW); Shi Ning JU, Hsinchu City (TW); Lin-Yu HUANG, Hsinchu (TW); Kuo-Cheng CHIANG, Zhubei City (TW)

(73) Assignee: Taiwan Semiconductor Manufacturing Company, Ltd., Hsinchu (TW)

(21) Appl. No.: 19/290,450

(22) Filed: Aug. 5, 2025

Related U.S. Application Data
(63) Continuation of application No. 18/186,754, filed on Mar. 20, 2023.
(60) Provisional application No. 63/350,701, filed on Jun. 9, 2022.
(60) Provisional application No. 63/378,799, filed on Oct. 7, 2022.

(51) Int. Cl. H01L 23/00; H01L 23/31

(52) U.S. Cl. CPC H01L 23/562; H01L 23/3128; H01L 24/05; H01L 24/32; H01L 2224/05188; H01L 2224/32157

(57) ABSTRACT

The present disclosure describes a method to form a semiconductor structure having an oxide structure on a wafer edge. The method includes forming a device layer on a first substrate, forming an interconnect layer on the device layer, forming an oxide structure on a top surface and along a sidewall surface of the interconnect layer, forming a bonding layer on the oxide structure and the interconnect layer, and bonding the device layer to a second substrate with the bonding layer.

### CROSS-REFERENCE TO RELATED APPLICATION

This application is a continuation application of U.S. Non-Provisional patent application Ser. No. 18/186,754, filed on Mar. 20, 2023, titled “Protection Layer for Semiconductor Devices,” which claims the benefit of U.S. Provisional Patent Application No. 63/350,701, titled “Protection Layer for Semiconductor Device,” filed Jun. 9, 2022, and U.S. Provisional Patent Application No. 63/378,799, titled “Protection Layer for Semiconductor Device,” filed Oct. 7, 2022, the disclosures of which are incorporated by reference in their entireties.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down allows more semiconductor devices to be integrated into a given area. Semiconductor devices can be stacked vertically to scale down the dimensions, increase performance, and reduce cost.

Wafer bonding is a technique to stack the semiconductor devices vertically. Wafer thinning can be used in the wafer bonding process to manufacture a semiconductor chip with the vertical stack of semiconductor devices. During the wafer thinning process, a grinding process can be performed on the backside of a semiconductor wafer and may damage the semiconductor wafer's edge. Subsequently, an edge trimming process can be performed to remove the outer edge of the semiconductor wafer.

### BRIEF DESCRIPTION OF THE DRAWINGS

Aspects of the present disclosure are best understood from the following detailed description when read with the accompanying figures.

FIGS. 1-3 illustrate cross-sectional views of semiconductor devices having a protection layer on a wafer edge, in accordance with some embodiments.

FIG. 4 is a flow diagram of a method for fabricating a semiconductor device having a protection layer on a wafer edge, in accordance with some embodiments.

FIGS. 5-15 illustrate various cross-sectional views of a semiconductor device having a protection layer on a wafer edge at various stages of its fabrication process, in accordance with some embodiments.

FIG. 16 is a flow diagram of a method for fabricating another semiconductor device having a protection layer on a wafer edge, in accordance with some embodiments.

FIGS. 17-24 illustrate various cross-sectional views of another semiconductor device having a protection layer on a wafer edge at various stages of its fabrication process, in accordance with some embodiments.

FIG. 25 is a flow diagram of a method for fabricating yet another semiconductor device having a protection layer on a wafer edge, in accordance with some embodiments.

FIGS. 26-29 illustrate various cross-sectional views of a semiconductor device having a protection layer on a wafer edge at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” and “exemplary” indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

With the continuous scaling down of semiconductor devices, three-dimensional (3D) integrated circuits (ICs) are developed to resolve the limitations of the number and length of interconnections between semiconductor devices as the number of semiconductor devices increases. The development of 3D ICs requires wafer bonding for backside processes and device layer transfer and integration. In wafer bonding, two semiconductor wafers are bonded together to form a 3D structure without the need of an intervening substrate or device. One semiconductor wafer can be a carrier wafer and the other semiconductor wafer can be a device wafer having semiconductor devices. A bonding layer, such as silicon oxide, can be formed on each semiconductor wafer. The carrier wafer can be flipped and placed on top of the device wafer, with the bonding layers of these two semiconductor wafers in contact. After a bonding anneal, silicon-oxygen-silicon (Si—O—Si) bonds can form at the interface of the bonding layers and can bond the two semiconductor wafers together. This bonding process can be referred to as “wafer fusion bonding.” The bond strength of the wafer fusion bonding can be sufficient to be compatible with subsequent semiconductor manufacturing processes.

Wafer thinning is used in conjunction with wafer bonding to provide a semiconductor chip including a vertical stack of at least two semiconductor dies. One of the two bonded wafers may be thinned after bonding. Bonded and thinned semiconductor wafers may be subsequently diced to form multiple semiconductor chips, which can have higher density, an increased number of functions, and/or faster operational speed provided through vertical bonding of at least two semiconductor dies. Edge regions of a wafer that do not include bonded portions of the semiconductor dies may be trimmed during the wafer thinning process to prevent the thinned wafer edge from breaking off and the bonded wafer assembly from peeling. However, functional dies adjacent to the wafer edge can be damaged by defects generated during the thinning process and subsequent backside processes. Additionally, dielectric materials isolating interconnect structures can be damaged and the interconnect structures can be exposed to introduce connection issues. Moreover, the dielectric materials can absorb water vapor, which can damage the functional dies adjacent to the wafer edge.

Various embodiments in the present disclosure provide example methods for forming a semiconductor device having a protection layer on the wafer edge and example semiconductor devices. According to some embodiments, the semiconductor device can include a bonding layer to bond a device layer to a carrier substrate. A protection layer can be disposed on a top surface of the carrier substrate and a sidewall surface of the device layer. In some embodiments, the protection layer can include a high etch selectivity material to protect functional dies, dielectric materials, and interconnect structures at the wafer edge from damage during the substrate thinning process and subsequent backside process. In some embodiments, the semiconductor device can include an oxide structure on a top surface and along a sidewall surface of the device layer. The oxide structure can increase the distance between the trimmed wafer edge and the functional dies, thus reducing damage to the functional dies during the trimming process. In some embodiments, with the protection layer and the oxide structure, the defects at the wafer edge can be reduced by about 10% to about 50%.

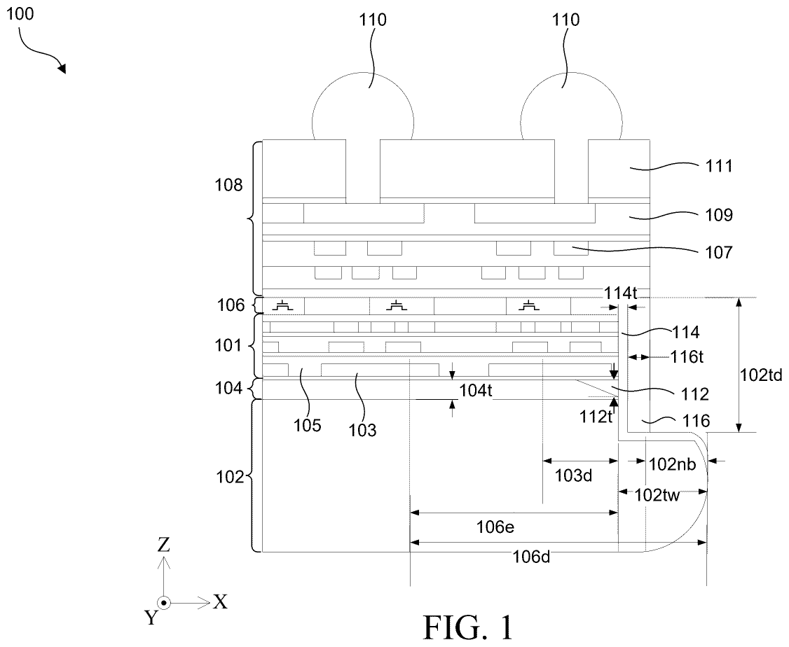

FIG. 1 illustrates a cross-sectional view of a semiconductor device 100 having first and second oxide structures 112 and 116 on a wafer edge, in accordance with some embodiments. First and second oxide structures 112 and 116 can protect semiconductor device 100 at the wafer edge. As shown in FIG. 1, semiconductor device 100 can include a substrate 102, a bonding layer 104, a front-side interconnect layer 101, a device layer 106, a backside interconnect layer 108, bump contacts 110, first oxide structure 112, an oxide layer 114, and second oxide structure 116.

In some embodiments, substrate 102 can be a carrier substrate without any semiconductor devices. Referring to FIG. 1, substrate 102 can include a semiconductor material, such as silicon. In some embodiments, substrate 102 includes a crystalline silicon substrate (e.g., wafer). In some embodiments, substrate 102 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 102 can be doped (e.g., p-type substrate or n-type substrate). In some embodiments, substrate 102 can be doped with p-type dopants (e.g., boron, indium, aluminum, or gallium) or n-type dopants (e.g., phosphorus or arsenic). In some embodiments, substrate 102 can have a thickness ranging from about 700 μm to about 800 μm.

Referring to FIG. 1, bonding layer 104 can bond front-side interconnect layer 101 and device layer 106 to substrate 102. In some embodiments, bonding layer 104 can include a dielectric material, such as silicon oxide (SiOₓ), silicon hydroxide (SiOH), silicon oxynitride (SiON), silicon nitride (SiNₓ), silicon oxycarbide (SiOC), silicon oxynitricarbide (SiOCN), tetraethyl orthosilicate (TEOS), un-doped silica glass (USG), high density plasma oxide (HDP SiOₓ), and a combination thereof. The dielectric material can bond front-side interconnect layer 101 and substrate 102. In some embodiments, bonding layer 104 can have a vertical dimension 104t (e.g., thickness) along a Z-axis ranging from about 20 nm to about 2000 nm.

Referring to FIG. 1, device layer 106 can be disposed between bonding layer 104 and backside interconnect layer 108. In some embodiments, device layer 106 can include one or more devices, such as MOSFETs, finFETs, gate-all-around (GAA) FETs, nanostructure transistors, and other active devices or passive devices. In some embodiments, the nanostructure transistors can include nanosheet transistors, nanowire transistors, multi-bridge channel transistors, and nano-ribbon transistors. The nanostructure transistors can provide a channel in a stacked nanostructure configuration. Front-side interconnect layer 101 can be disposed between device layer 106 and bonding layer 104. In some embodiments, semiconductor device 100 can have an etch stop layer (ESL) between front-side interconnect layer 101 and bonding layer 104 (not shown in FIG. 1). In some embodiments, the ESL can include a dielectric material, such as TEOS, silicon carbonitride (SiCN), and SiNₓ. In some embodiments, the ESL can have a thickness ranging from about 10 nm to about 100 nm.

In some embodiments, as shown in FIG. 1, front-side interconnect layer 101 can include front-side interconnect structures 103 and front-side intermetallic dielectric layers 105. Front-side interconnect structures 103 can electrically connect the one or more devices in device layer 106 to each other and other parts of semiconductor device 100 or the IC package including semiconductor device 100. In some embodiments, front-side interconnect structures 103 can include metal vias and metal lines. Metal vias can connect metal lines above and below metal vias in a Z-direction. Metal lines can extend in an X- or Y-direction. Each one of connected metal vias and metal lines can form a conductive interconnect layer to electrically connect the one or more devices in device layer 106 and other parts of semiconductor device 100. Though front-side interconnect layer 101 in FIG. 1 includes three conductive interconnect layers, front-side interconnect layer 101 can include any suitable number of conductive interconnect layers. In some embodiments, metal vias and metal lines can include any suitable conductive materials, such as tungsten (W), aluminum (Al), copper (Cu), cobalt (Co), titanium (Ti), tantalum (Ta), ruthenium (Ru), a silicide material, and a conductive nitride material. In some embodiments, a metal liner can be disposed between the metal lines or metal vias and front-side intermetallic dielectric layers 105. The metal liner can include tantalum nitride (TaN), ruthenium cobalt (RuCo), or other suitable conductive materials to protect front-side interconnect structures 103 from defects diffused from front-side intermetallic dielectric layers 105. In some embodiments, the metal liner can have a single layer or a bi-layer structure with a thickness ranging from about 1 nm to about 10 nm.

Front-side intermetallic dielectric layers 105 can include one or more insulating layers to provide electrical insulation between front-side interconnect structures 103 in front-side interconnect layer 101, as shown in FIG. 1. In some embodiments, front-side intermetallic dielectric layers 105 can include a low-k dielectric material (e.g., material with a dielectric constant less than about 3.9), an extremely low-k dielectric material (e.g., material with a dielectric constant less than about 2.5), other suitable materials, and/or combinations thereof. In some embodiments, the low-k dielectric material can include SiOₓ, SiOC, SiOCN, or other suitable dielectric materials. In some embodiments, the low-k dielectric material in front-side intermetallic dielectric layers 105 can reduce interferences between adjacent front-side interconnect structures 103.

Referring to FIG. 1, backside interconnect layer 108 can be disposed on device layer 106 and connect device layer 106 to external connections through bump contacts 110. In some embodiments, backside interconnect layer 108 can include backside interconnect structures 107, backside intermetallic dielectric layers 109, backside metal routing layer 150, and bump contacts 170. In some embodiments, backside interconnect structures 107 can include metal lines and metal vias that are the same as front-side interconnect structures 103. Though backside interconnect structures 107 in FIG. 1 includes three conductive interconnect layers, backside interconnect structures 107 can include any suitable number of conductive interconnect layers. In some embodiments, backside interconnect structures 107 can include a conductive material the same as or different from front-side interconnect structures 103. In some embodiments, backside interconnect structures 107 can include W, Al, Cu, Co, Ti, Ta, Ru, a silicide material, a conductive nitride material, or other suitable conductive materials.

Backside intermetallic dielectric layers 109 can include one or more insulating layers to provide electrical insulation between backside interconnect structures 107 in backside interconnect layer 108, as shown in FIG. 1. In some embodiments, backside intermetallic dielectric layers 109 can include a low-k dielectric material the same as or different from front-side intermetallic dielectric layers 105. In some embodiments, backside intermetallic dielectric layers 109 can include SiOₓ, SiOC, SiOCN, or other suitable dielectric materials.

Referring to FIG. 1, backside metal routing layer 111 and bump contacts 110 can connect backside interconnect structures 107 to other parts of semiconductor device 100 and/or external devices. In some embodiments, backside metal routing layer 111 can include Al and can have a thickness ranging from about 1.3 μm to about 4.0 μm. In some embodiments, bump contacts 110 can include metals, such as Al, Ti, Cu, and chromium (Cr).

Referring to FIG. 1, first oxide structure 112 can be disposed between bonding layer 104 and front-side interconnect layer 101. In some embodiments, first oxide structure 112 can be disposed along a sidewall surface of bonding layer 104 and in contact with front-side interconnect layer 101. In some embodiments, first oxide structure 112 can be a tapered structure wedged between bonding layer 104 and front-side interconnect layer 101. In some embodiments, first oxide structure 112 can include an oxide material, such as SiOₓ. In some embodiments, first oxide structure 112 can include a dielectric material different from the dielectric material of bonding layer 104. In some embodiments, first oxide structure 112 can include any suitable dielectric materials. In some embodiments, first oxide structure 112 can have a thickness 112t adjacent to the edge of front-side interconnect layer 101 ranging from about 0.5 μm to about 2 μm.

In some embodiments, with first oxide structure 112, a distance 102nb of the non-bonding region at the edge of substrate 102 can be about 0.5 mm to about 1.1 mm. The non-bonding region is the region between substrate 102 and front-side interconnect layer 101 not bonded by bonding layer 104 due to edge roll-off/rounding. As a result, semiconductor device 100 can have a smaller trim edge width 102tw ranging from about 0.9 mm to about 1.5 mm. In some embodiments, semiconductor device 100 can have a trim edge depth 102td ranging from about 25 μm to about 100 μm. In some embodiments, functional dies in device layer 106 can be disposed away from the edge of substrate 501 by a distance 106d ranging from about 2.8 mm to about 3.2 mm. With a smaller trim edge width 102tw, a distance 106e between the functional dies and the edge of device layer 106 (i.e., trim edge) can be increased to about 1.3 mm to about 2.3 mm. Therefore, the first oxide structure 112 can reduce the damage to the functional dies during the trimming and thinning processes.

In some embodiments, with first oxide structure 112, a distance 103d between front-side interconnect structures 103 and the edge of device layer 106 (i.e., trim edge) can be increased to about 0.7 mm to about 1.3 mm. As a result, the damage to front-side interconnect structures 103 during the trimming process can be reduced.

Referring to FIG. 1, oxide layer 114 can be disposed on a top surface of substrate 102 and sidewall surfaces of bonding layer 104, first oxide structure 112, front-side interconnect layer 101, and device layer 106. In some embodiments, oxide layer 114 can include an oxide material, such as SiOₓ. In some embodiments, oxide layer 114 can include any suitable dielectric materials. In some embodiments, oxide layer 114 can have a thickness 114t ranging from about 100 nm to about 300 nm. In some embodiments, oxide layer 114 can protect front-side intermetallic dielectric layers 105 and prevent water vapor absorption. If thickness 114t is less than about 100 nm, oxide layer 114 may not prevent front-side intermetallic dielectric layers 105 from water vapor absorption. If thickness 114t is greater than about 300 nm, the manufacturing cost may increase.

Referring to FIG. 1, second oxide structure 116 can be disposed on oxide layer 114 and along sidewall surfaces of bonding layer 104, first oxide structure 112, front-side interconnect layer 101, and device layer 106. In some embodiments, second oxide structure 116 can include an oxide material, such as SiOₓ. In some embodiments, second oxide structure 116 can include any suitable dielectric materials. In some embodiments, second oxide structure 116 can have a thickness 116t ranging from about 0.5 μm to about 4 μm. In some embodiments, second oxide structure 116 can protect oxide layer 114, front-side interconnect layer 101, and device layer 106 during subsequent backside processes. If thickness 116t is less than about 0.5 μm, second oxide structure 116 may not protect oxide layer 114, front-side interconnect layer 101, and device layer 106. If thickness 116t is greater than about 4 μm, the manufacturing cost may increase.

In some embodiments, first and second oxide structures 112 and 116 can reduce distance 102nb of the non-bonding region and trim edge width 102tw. As a result, distance 106e between the functional dies and the edge of device layer 106 (i.e., trim edge) can increase. Therefore, first and second oxide structures 112 and 116 can protect device layer 106 and prevent damage during the trimming, thinning, and subsequent backside processes. In some embodiments, first and second oxide structures 112 and 116 can reduce the defects at the wafer edge by about 10% to about 50%.

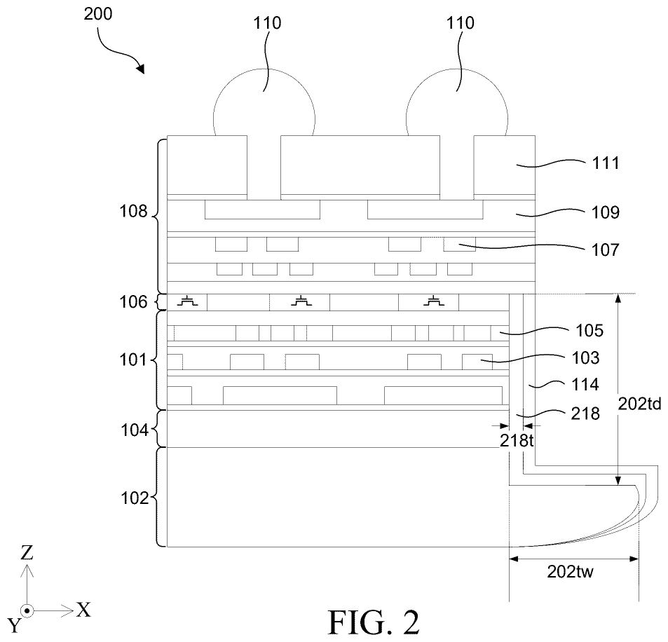

FIG. 2 illustrates a cross-sectional view of semiconductor device 200 having a protection layer 218 on a wafer edge, in accordance with some embodiments. Referring to FIG. 2, semiconductor device 200 can include substrate 102, bonding layer 104, front-side interconnect layer 101, device layer 106, backside interconnect layer 108, bump contacts 110, protection layer 218, and oxide layer 114. Elements in FIG. 2 with the same annotations as elements in FIG. 1 are described above.

As shown in FIG. 2, protection layer 218 can be disposed on a top surface of substrate 102 and sidewall surfaces of bonding layer 104, front-side interconnect layer 101, and device layer 106. In some embodiments, semiconductor device 200 can have a trim edge width 202tw ranging from about 0.9 mm to about 4.5 mm. In some embodiments, semiconductor device 200 can have a trim edge depth 202td ranging from about 25 μm to about 100 μm.

In some embodiments, protection layer 218 can cover the trim edge to protect bonding layer 104, front-side interconnect layer 101, and device layer 106. In some embodiments, protection layer 218 can include a dielectric material, such as Ti, titanium nitride (TiN), silicon carbide (SiC), SiCN, SiOₓ, SiNₓ, and other suitable protective materials. The protective material in protection layer 218 can have a high etch selectivity (e.g., from about 2 to about 50) with regard to the substrate material (e.g., Si) of device layer 106. The term “etch selectivity” can refer to the ratio of the etch rates of two different materials under the same etching conditions. The high etch selectivity of protection layer 218 can protect device layer 106 during the thinning process and subsequent backside processes. In some embodiments, protection layer 218 can prevent water vapor absorption of the low-k material in front-side interconnect layer 101. In some embodiments, oxide layer 114 can be disposed on protection layer 218 to further protect front-side interconnect layer 101 and prevent water vapor absorption. In some embodiments, protection layer 218 can prevent exposure of the interconnect structures in front-side interconnect layer 101 at the trim corner. In some embodiments, protection layer 218 can improve trim depth control and reduce edge defects generated during lithography and electroplating processes.

In some embodiments, protection layer 218 can have a thickness 218t ranging from about 0.1 μm to about 1 μm. If thickness 218t is less than about 0.1 μm, protection layer 218 may not protect device layer 106, front-side interconnect layer 101, and bonding layer 104 during the thinning process and subsequent backside processes. If thickness 218t is greater than about 1 μm, the manufacturing cost may increase.

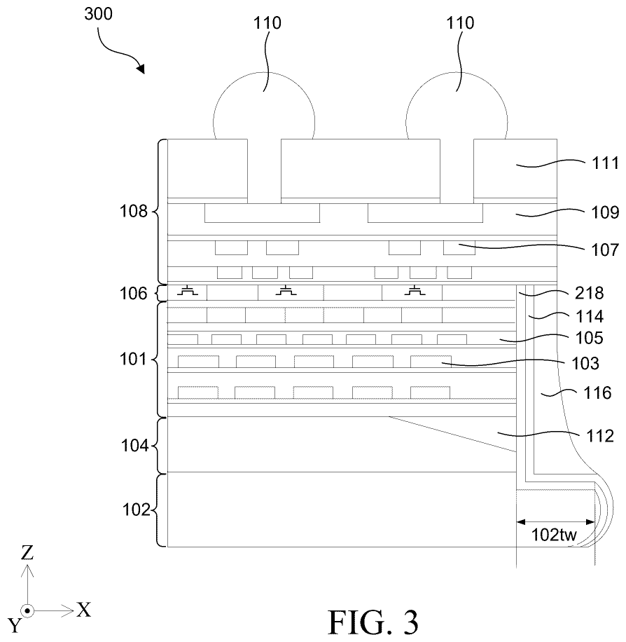

FIG. 3 illustrates a cross-sectional view of semiconductor device 300 having a protection layer 218 and first and second oxide structures 112 and 116 on a wafer edge, in accordance with some embodiments. Referring to FIG. 3, semiconductor device 300 can include substrate 102, bonding layer 104, device layer 106, front-side interconnect layer 101, backside interconnect layer 108, bump contacts 110, protection layer 218, first oxide structure 112, oxide layer 114, and second oxide structure 116. Elements in FIG. 3 with the same annotations as elements in FIGS. 1 and 2 are described above.

As shown in FIG. 3, first oxide structure 112 can be disposed between bonding layer 104 and front-side interconnect layer 101. In some embodiments, first oxide structure 112 can be disposed along a sidewall surface of bonding layer 104 and in contact with front-side interconnect layer 101. In some embodiments, first oxide structure 112 can be a tapered structure wedged between bonding layer 104 and front-side interconnect layer 101.

Referring to FIG. 3, protection layer 218 can be disposed on a top surface of substrate 102 and sidewall surfaces of bonding layer 104, first oxide structure 112, front-side interconnect layer 101, and device layer 106. Protection layer 218 can cover the trim edge of semiconductor device 300 and protect bonding layer 104, front-side interconnect layer 101, and device layer 106. In some embodiments, oxide layer 114 can be disposed on protection layer 218. Second oxide structure 116 can be disposed on oxide layer 114 and along sidewalls of bonding layer 104, first oxide structure 112, front-side interconnect layer 101, and device layer 106.

In some embodiments, first and second oxide structures 112 and 116 can reduce trim edge width 102tw to a range of about 0.9 mm to about 1.5 mm. As a result, the distance between the functional dies and the edge of device layer 106 (i.e., trim edge) can increase. Therefore, first and second oxide structures 112 and 116 can protect device layer 106 and prevent damage during the trimming, thinning, and subsequent backside processes. Protection layer 218 can include the high etch selectivity material to further protect device layer 106 during the thinning process and subsequent backside processes. In some embodiments, protection layer 218 can prevent water vapor absorption of the low-k material in front-side interconnect layer 101. In some embodiments, protection layer 218 can prevent exposure of the interconnect structures in front-side interconnect layer 101 at the trim corner after the trimming process. In some embodiments, protection layer 218 can improve trim depth control and reduce edge defects generated during lithography and electroplating processes. With protection layer 218 and first and second oxide structures 112 and 116, edge defects of semiconductor device 300 can be further reduced. Functional dies, interconnect structures, and intermetallic dielectric materials in device layer 106 and front-side interconnect layer 101 can be better protected. In some embodiments, protection layer 218 and first and second oxide structures 112 and 116 can reduce the defects at the wafer edge by about 20% to about 50%.

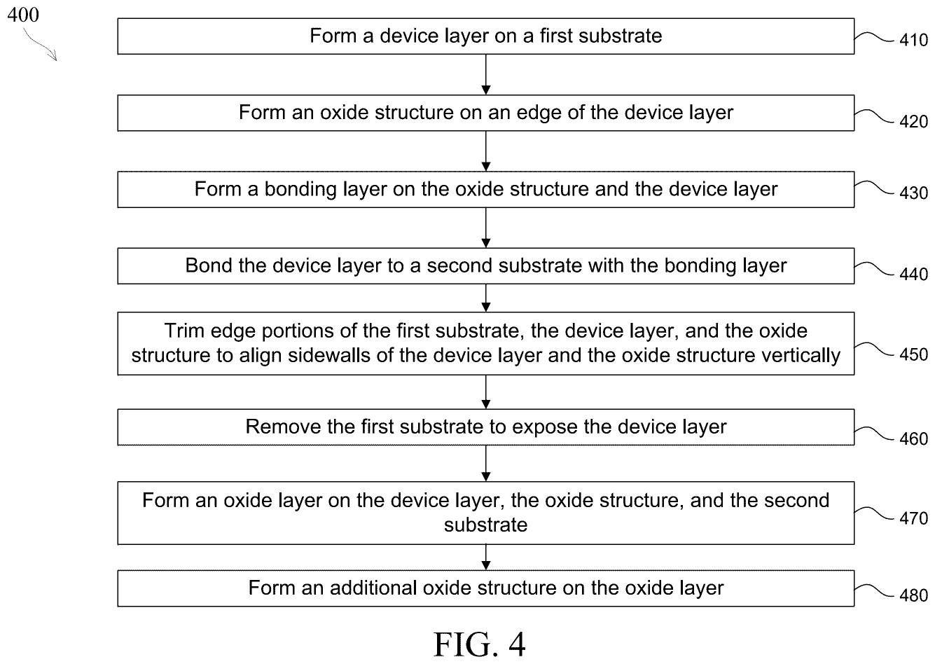

FIG. 4 is a flow diagram of a method 400 for fabricating semiconductor device 100 having first and second oxide structures 112 and 116 at the wafer edge, in accordance with some embodiments. Method 400 may not be limited to semiconductor device 100 and can be applicable to other devices that would benefit from the oxide structures at the wafer edge. Additional fabrication operations may be performed between various operations of method 400 and may be omitted merely for clarity and ease of description. Additional processes can be provided before, during, or after method 400; one or more of these additional processes are briefly described herein. Moreover, not all operations may be needed to perform the disclosure provided herein. Additionally, some of the operations may be performed simultaneously or in a different order than shown in FIG. 4. In some embodiments, one or more other operations may be performed in addition to or in place of the presently-described operations.

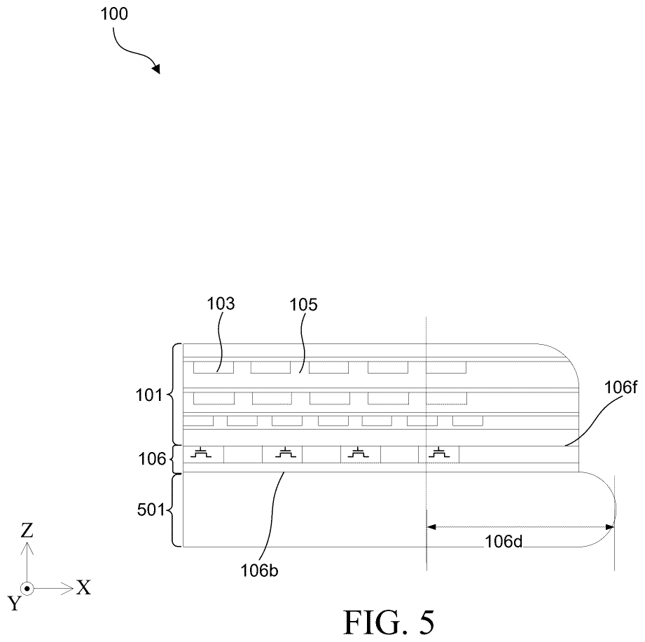

For illustrative purposes, the operations illustrated in FIG. 4 will be described with reference to the example fabrication process for semiconductor device 100 as illustrated in FIGS. 1 and 5-15. FIGS. 5-15 illustrate cross-sectional views of semiconductor device 100 at various stages of its fabrication process, in accordance with some embodiments. Elements in FIGS. 5-15 with the same annotations as elements in FIG. 1 are described above.

In referring to FIG. 4, method 400 begins with operation 410 and the process of forming a device layer on a first substrate. For example, as shown in FIG. 5, device layer 106 can be formed on substrate 501 and front-side interconnect layer 101 can be formed on device layer 106. In some embodiments, substrate 501 can include a semiconductor material the same as or different from the semiconductor material in substrate 102. In some embodiments, device layer 106 can have a front-side 106f and a backside 106b. Front-side interconnect layer 101 on front-side 106f of device layer 106 can have a roll-off region around the edge, which can be caused by the polishing processes. In some embodiments, device layer 106 can include one or more devices. Front-side interconnect layer 101 can include front-side interconnect structures 103, and front-side intermetallic dielectric layers 105 on front-side 106f. Backside 106b of device layer 106 can be disposed on substrate 501. In some embodiments, functional dies in device layer 106 can be disposed away from the edge of semiconductor device 100 by a distance 106d ranging from about 2.8 mm to about 3.2 mm. As shown in FIG. 5, the edge of substrate 501 can extend beyond sidewall surfaces of device layer 106, because device layer 106 may not form on the roll-off edge of substrate 501.

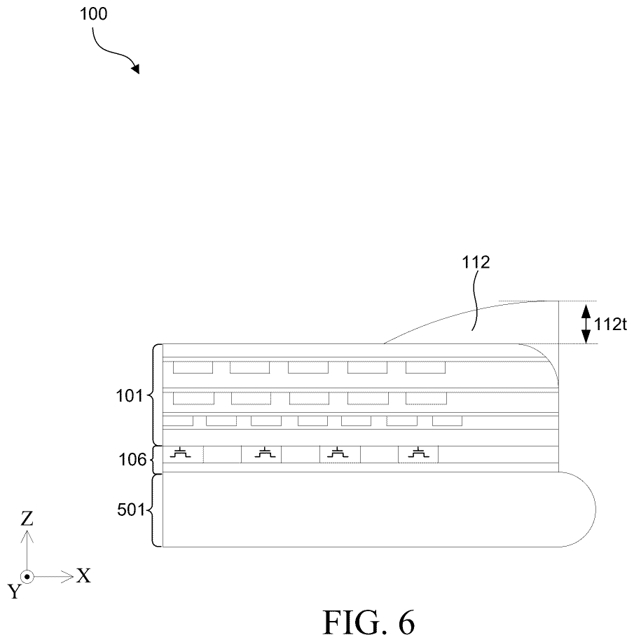

Referring to FIG. 4, in operation 420, an oxide structure is formed on an edge of the device layer. For example, as shown in FIG. 6, first oxide structure 112 can be formed on the edge of front-side interconnect layer 101 and device layer 106. In some embodiments, a flat pad (e.g., a plate, not shown in FIG. 6) can be placed on front-side interconnect layer 101 to cover front-side 106f. The edge roll-off region of front-side interconnect layer 101 may not be fully covered by the flat pad. An oxide material can be deposited on the edge roll-off region to form first oxide structure 112 by chemical vapor deposition (CVD) or other suitable deposition method at a temperature from about 85° C. to about 400° C. In some embodiments, at the edge of front-side interconnect layer 101, first oxide structure 112 can have a thickness 112t ranging from 0.5 μm to about 2 μm. In some embodiments, first oxide structure 112 can include SiOₓ or other suitable dielectric materials.

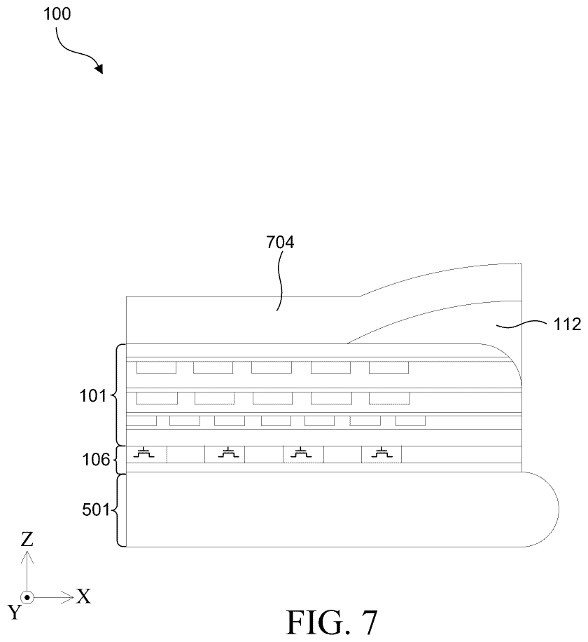

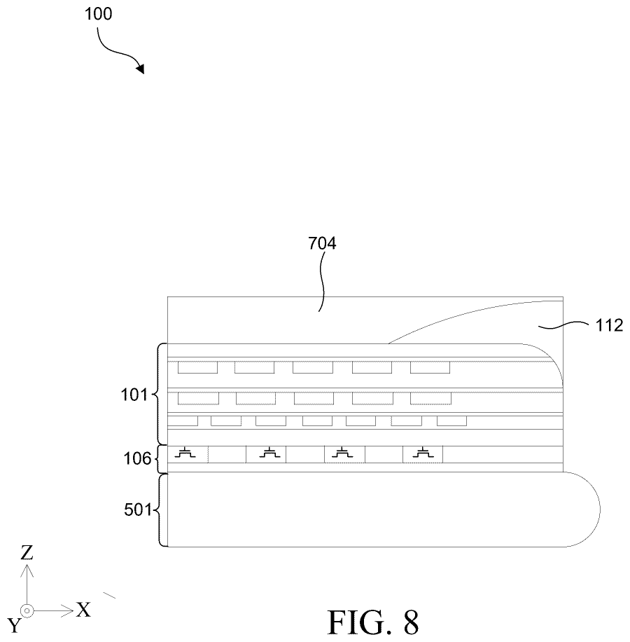

In operation 430 of FIG. 4, a bonding layer is formed on the oxide structure and the device layer. For example, as shown in FIG. 7, bonding layer 704 can be deposited on first oxide structure 112 and front-side interconnect layer 101. In some embodiments, bonding layer can be deposited by CVD, atomic layer deposition (ALD), plasma enhanced CVD (PECVD), high density plasma (HDP), or other suitable deposition methods. In some embodiments, bonding layer 704 can include a dielectric material, such as SiOₓ, SiOH, SION, SiNₓ, SiOC, SiOCN, and a combination thereof. In some embodiments, as shown in FIG. 8, a chemical mechanical polishing (CMP) process can be performed on bonding layer 704 to co-planarize top surfaces of bonding layer 704 and first oxide structure 112. In some embodiments, bonding layer 704 can have a thickness ranging from about 0.2 μm to about 2 μm.

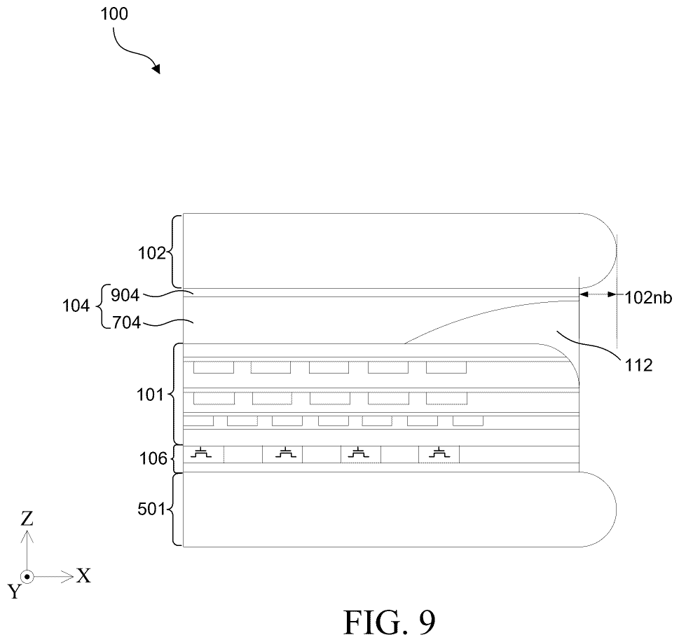

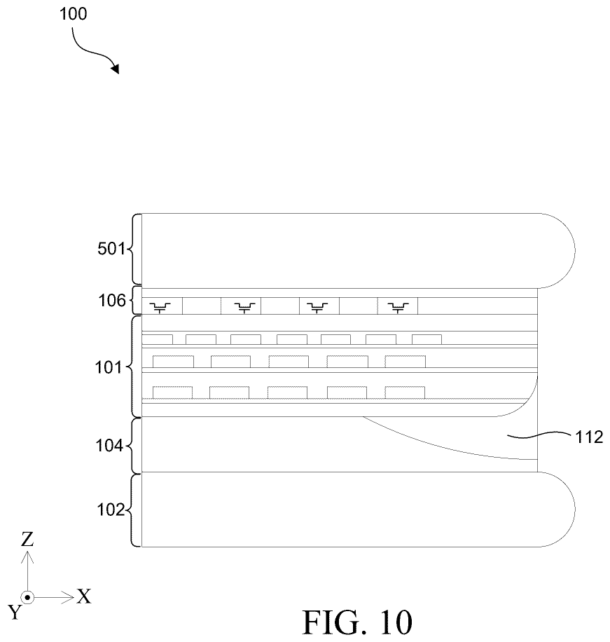

In operation 440 of FIG. 4, the device layer is bonded to a second substrate with the bonding layer. For example, as shown in FIG. 9, substrate 102 can have a bonding layer 904 and device layer 106 and front-side interconnect layer 101 can be bonded to substrate 102 with bonding layers 904 and 704. After bonding device layer 106 and front-side interconnect layer 101 to substrate 102, bonding layers 904 and 704 can form bonding layer 104. As shown in FIG. 9, after the bonding process, the edge of substrate 102 can extend beyond sidewall surfaces of device layer 106 by a distance 102nb. Front-side interconnect layer 101 and the roll-off edge regions of substrate 102 may not bonded, for which they can be referred to as “non-bonding regions.” With first oxide structure 112, more regions between substrate 102 and front-side interconnect layer 101 can be bonded, and thus distance 102nb can be reduced. In some embodiments, distance 102nb can be about 0.5 mm to about 1.1 mm. In some embodiments, the functional dies in device layer 106 is away from the edge of substrate 501 by a distance 106d ranging from about 2.8 mm to about 3.2 mm. With a smaller distance 102nb of the non-bonding regions, functional dies in device layer 106 can be further from the non-bonding regions, which can be removed in the subsequent trimming process. After the bonding process, as shown in FIG. 10, semiconductor device 100 can be flipped over to have substrate 501 on top.

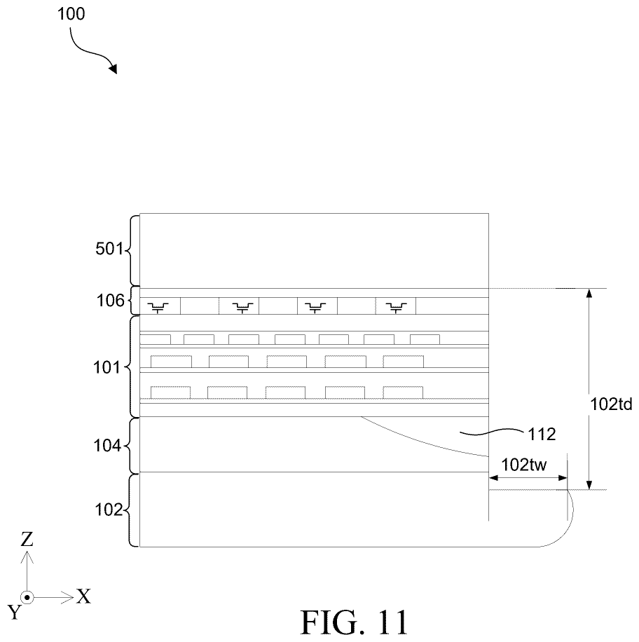

In operation 450 of FIG. 4, edge portions of the first substrate, the device layer, the oxide structure are trimmed to vertically align sidewalls of the device layer and the oxide structure. For example, as shown in FIG. 11, edge portions of substrate 501, front-side interconnect layer 101, device layer 106, and first oxide structure 112 can be trimmed to vertically align sidewalls of device layer 106, front-side interconnect layer 101, first oxide structure 112, and substrate 501. With first oxide structure 112, the non-bonding regions can have a smaller distance 102nb. Therefore, the trimming process can have a smaller trim edge width 102tw ranging from about 0.9 mm to about 1.5 mm. As a result, the functional dies in device layer 106 can be farther from the trimming edge and the functional dies may not be damaged by the trimming process. In some embodiments, semiconductor device 100 can have a trim edge depth 102td ranging from about 25 μm to about 100 μm.

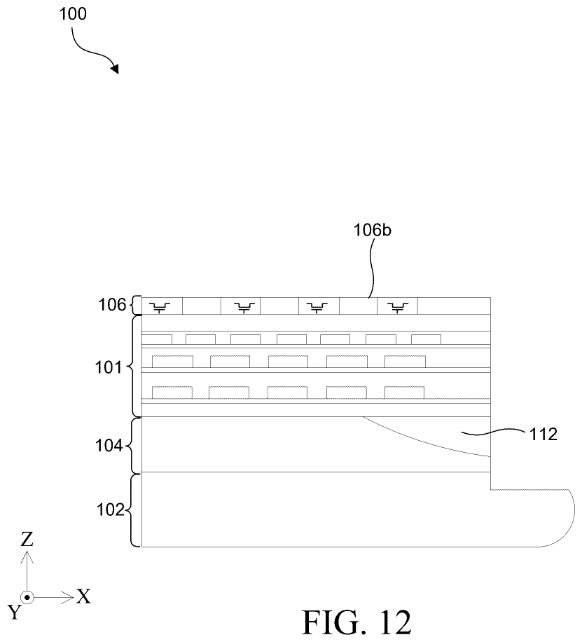

In operation 460 of FIG. 4, the first substrate is removed to expose the device layer. For example, as shown in FIG. 12, substrate 501 can be removed to expose device layer 106. In some embodiments, substrate 501 can be removed by a substrate thinning process. The substrate thinning process can include multiple processes, such as grinding, polishing, and etching, to remove substrate 501. After the substrate thinning process, backside 106b of device layer 106 can be exposed.

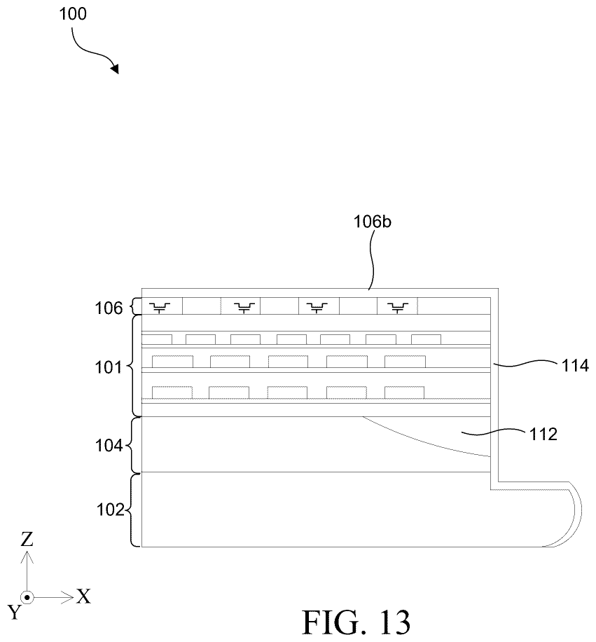

In operation 470 of FIG. 4, an oxide layer is formed on the device layer, the oxide structure, and the second substrate. For example, as shown in FIG. 13, oxide layer 114 can be formed on device layer 106, first oxide structure 112, and substrate 102. In some embodiments, oxide layer 114 can be conformally deposited on device layer 106, first oxide structure 112, and substrate 102 by ALD, CVD, or other suitable deposition methods. In some embodiments, oxide layer 114 can include an oxide material, such as SiOₓ. In some embodiments, oxide layer 114 can include any suitable dielectric materials. In some embodiments, oxide layer 114 can have a thickness 114t ranging from about 100 nm to about 300 nm to protect front-side interconnect layer 101 and prevent water vapor absorption.

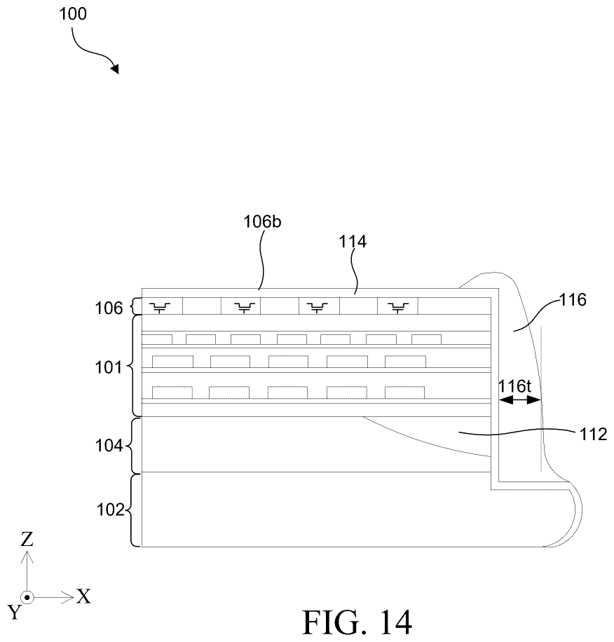

In operation 480 of FIG. 4, an additional oxide structure is formed on the oxide layer. For example, as shown in FIG. 14, second oxide structure 116 can be formed on oxide layer 114. Second oxide structure 116 can be formed along sidewalls of device layer 106, front-side interconnect layer 101, first oxide structure 112, and oxide layer 114. In some embodiments, a flat pad (e.g., a plate, not shown in FIG. 14) can be placed on device layer 106 to cover backside 106b. An oxide material can be deposited on the sidewall surfaces of oxide layer 114 by CVD, PECVD, or other suitable deposition methods. In some embodiments, second oxide structure 116 can include SiOₓ or other suitable dielectric materials. In some embodiments, second oxide structure 116 can have a thickness 116t ranging from about 0.5 μm to about 4 μm. In some embodiments, second oxide structure 116 can protect oxide layer 114 and device layer 106 during subsequent backside processes.

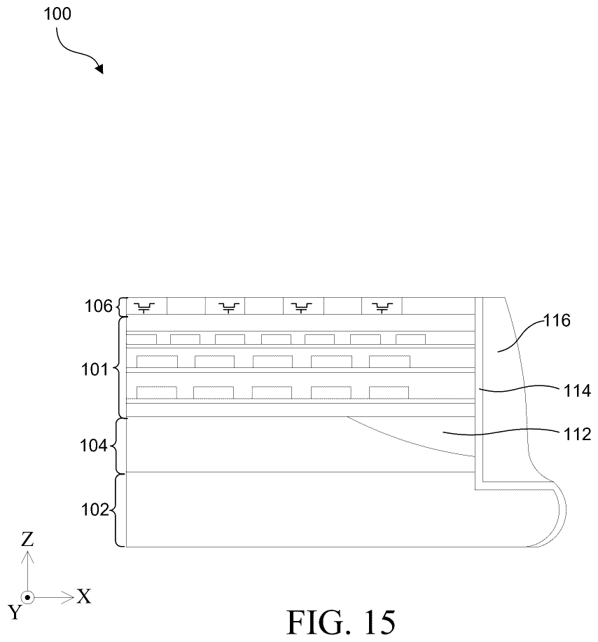

The formation of second oxide structure 116 can be followed by a CMP process, as shown in FIG. 15, to co-planarize top surfaces of device layer 106, oxide layer 114, and second oxide structure 116. The CMP process can be followed by the formation of backside interconnect layer 108 and bump contacts 110, as shown in FIG. 1. In some embodiments, backside interconnect layer 108 can include backside interconnects electrically connecting the one or more devices in device layer 106 to bump contacts 110 and external connections. In some embodiments, backside interconnect layer 108 can be formed by depositing one or more dielectric layers and forming the backside interconnects in the one or more dielectric layers. The backside interconnects can be connected to each other and the one or more devices in device layer 106. With first and second oxide structures 112 and 116, the functional dies in device layer 106 can be further away from the edge of substrate 102, device layer 106 and front-side interconnect layer 101 can be better protected during the backside processes, and thus edge defects can be reduced and damage to functional dies can be minimized.

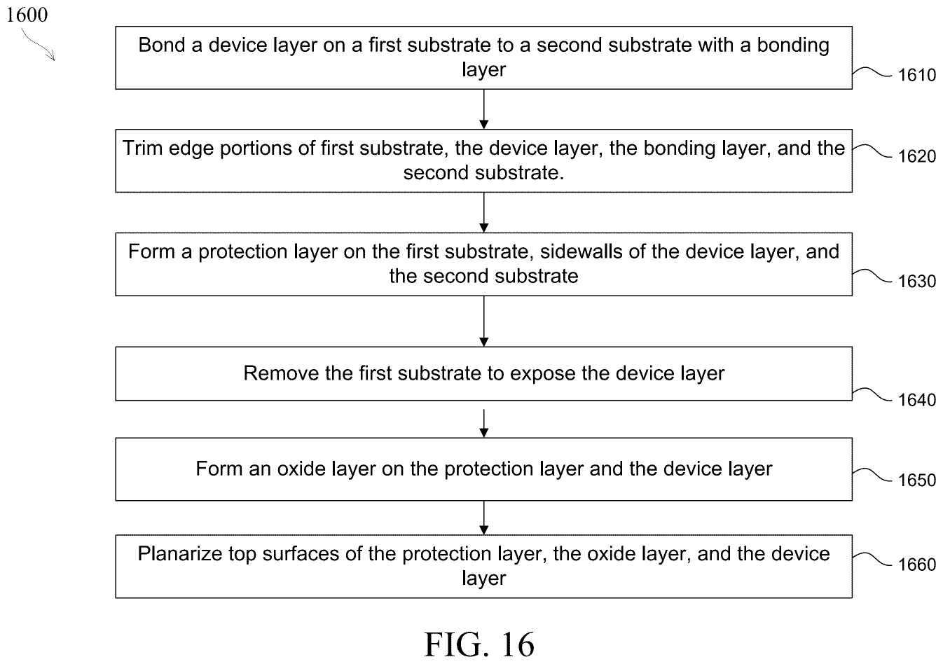

FIG. 16 is a flow diagram of a method 1600 for fabricating semiconductor device 200 having protection layer 218 at the wafer edge, in accordance with some embodiments. Method 1600 may not be limited to semiconductor device 200 and can be applicable to other devices that would benefit from the protection layer at the wafer edge. Additional fabrication operations may be performed between various operations of method 1600 and may be omitted merely for clarity and case of description. Additional processes can be provided before, during, or after method 1600; one or more of these additional processes are briefly described herein. Moreover, not all operations may be needed to perform the disclosure provided herein. Additionally, some of the operations may be performed simultaneously or in a different order than shown in FIG. 16. In some embodiments, one or more other operations may be performed in addition to or in place of the presently-described operations.

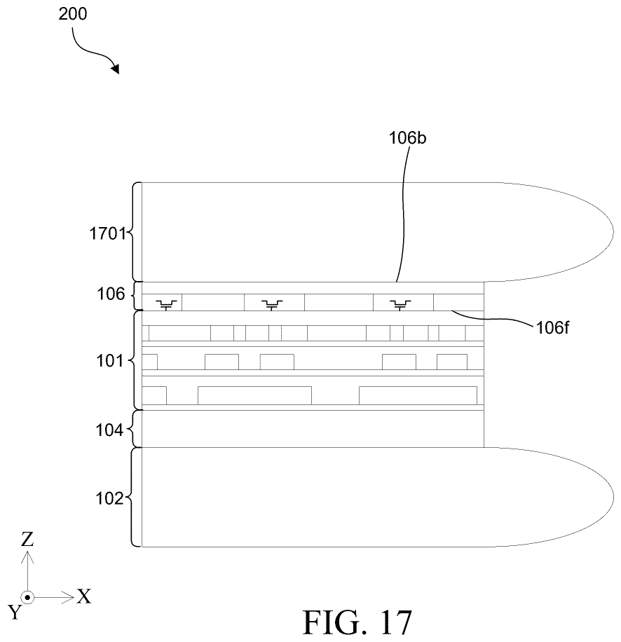

For illustrative purposes, the operations illustrated in FIG. 16 will be described with reference to the example fabrication process for semiconductor device 200 as illustrated in FIGS. 2 and 17-24. FIGS. 17-24 illustrate cross-sectional views of semiconductor device 200 at various stages of its fabrication process, in accordance with some embodiments. Elements in FIGS. 17-24 with the same annotations as elements in FIGS. 1 and 2 are described above.

In referring to FIG. 16, method 1600 begins with operation 1610 and the process of bonding a device layer on a first substrate to a second substrate with a bonding layer. For example, as shown in FIG. 17, device layer 106 and front-side interconnect layer 101 on substrate 1701 can be bonded to substrate 102 with a bonding layer 104. In some embodiments, substrate 1701 can include a semiconductor material the same as or different from the semiconductor material in substrate 102. In some embodiments, device layer 106 and front-side interconnect layer 101 can be formed on the semiconductor material of substrate 1701. In some embodiments, the processes in operation 1610 can be substantially the same as the processes in operations 410, 430, and 440 as shown in FIG. 4. Backside 106b of device layer 106 can be on substrate 1701. Front-side interconnect layer 101 on front-side 106f of device layer 106 can be bonded to substrate 102. After the bonding process, as shown in FIG. 17, semiconductor device 100 can be flipped over to have substrate 1701 on top.

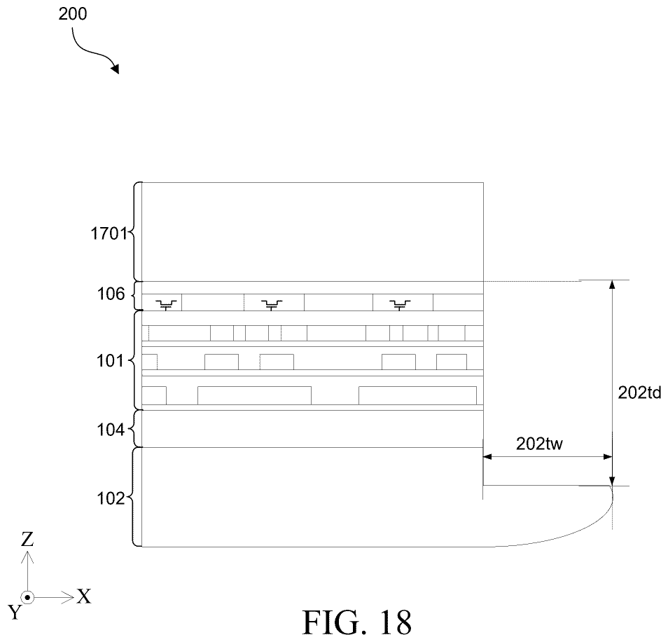

In operation 1620 of FIG. 16, edge portions of the first substrate, the device layer, the bonding layer, and the second substrate are trimmed. For example, as shown in FIG. 18, edge portions of substrate 1701, device layer 106, front-side interconnect layer 101, bonding layer 104, and substrate 102 can be trimmed to vertically align sidewalls of device layer 106, front-side interconnect layer 101, bonding layer 104, and substrate 1701. In some embodiments, the processes in operation 1620 can be substantially the same as the processes in operation 450 as shown in FIG. 4. In some embodiments, the trimming process can have a trim edge width 202tw ranging from about 0.9 mm to about 4.5 mm and a trim edge depth 202td ranging from about 25 μm to about 100 μm.

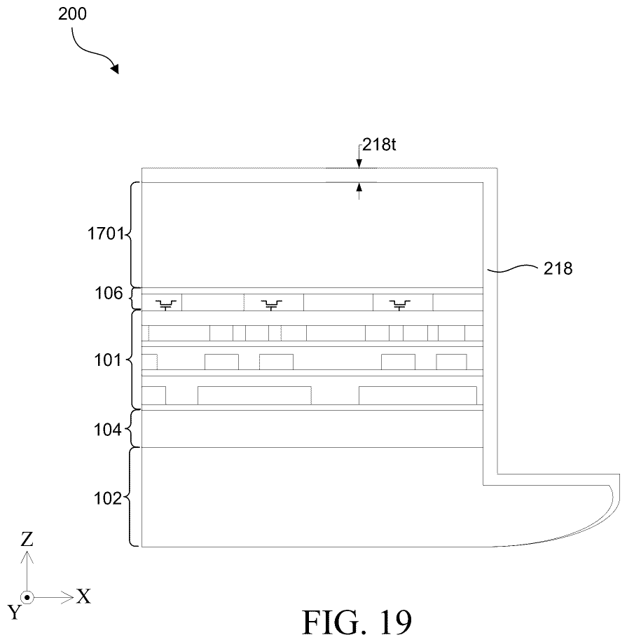

In operation 1630 of FIG. 16, a protection layer is formed on the first substrate, the sidewalls of the device layer, and the second substrate. For example, as shown in FIG. 19, protection layer 218 can be formed on substrate 102, sidewalls of device layer 106, front-side interconnect layer 101, and substrate 1701. In some embodiments, protection layer 218 can be conformally deposited on top surfaces of substrates 102 and 1701 and sidewall surfaces of device layer 106 and front-side interconnect layer 101 by ALD, CVD, or other suitable deposition methods. In some embodiments, protection layer 218 can have a thickness 218t ranging from about 0.1 μm to about 1 μm. In some embodiments, protection layer 218 can include a protective material, such as Ti, TiN, SiC, SiCN, SiOₓ, SiNₓ, and other suitable dielectric materials. The protective material in protection layer 218 can have a high etch selectivity (e.g., from about 2 to about 50) with regard to the semiconductor material in substrate 1701 (e.g., Si). The high etch selectivity of protection layer 218 can protect device layer 106 during the thinning process and subsequent backside processes. In some embodiments, protection layer 218 can prevent water vapor absorption of the low-k dielectric material in front-side interconnect layer 101. In some embodiments, protection layer 218 can prevent exposure of the interconnect structures in front-side interconnect layer 101 at the trim corner during the thinning process. In some embodiments, protection layer 218 can improve trim depth control and reduce edge defects generated during subsequent lithography and electroplating processes.

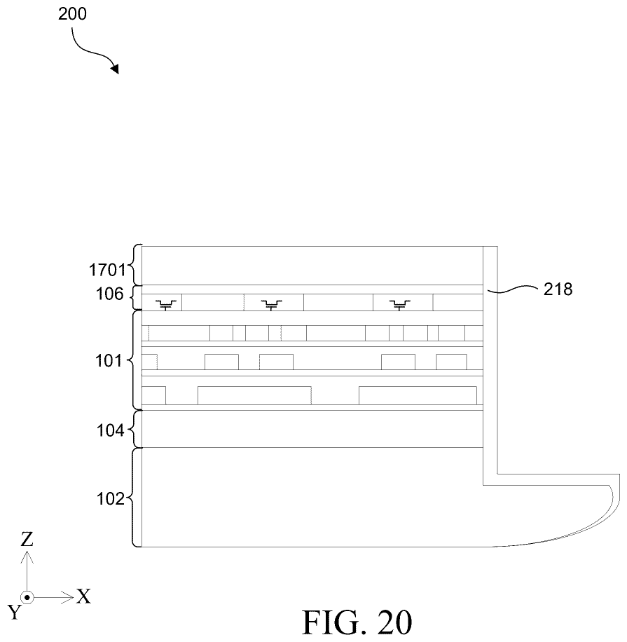

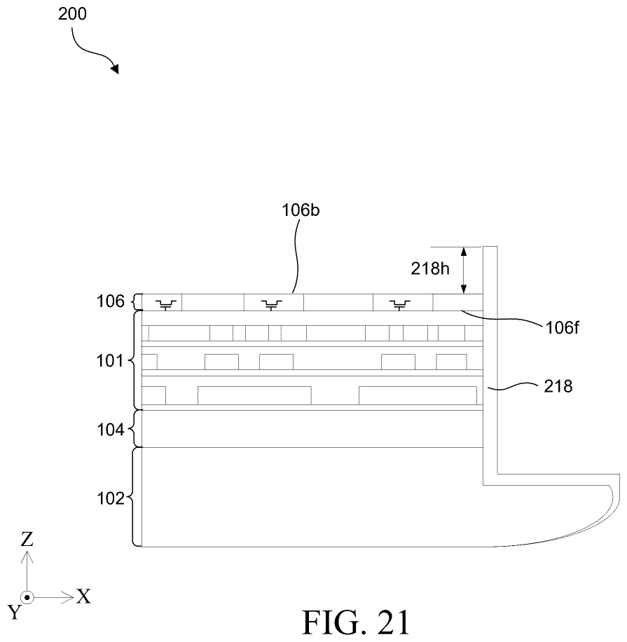

In operation 1640 of FIG. 16, the first substrate is removed to expose the device layer. For example, as shown in FIGS. 20 and 21, substrate 1701 can be removed to expose device layer 106. In some embodiments, the removal of substrate 1701 can be performed by one or more thinning processes. For example, a grinding process can remove a portion of substrate 1701 as shown in FIG. 20, and a set of dry etching and/or wet etching processes can remove the remaining portions of substrate 1701 as shown in FIG. 21. In some embodiments, due to the high etch selectivity of protection layer 218, after the removal of substrate 1701, a port of protection layer 218 can remain above backside 106b of device layer 106. In some embodiments, the portion of protection layer 218 above backside 106b can have a height 218h ranging from about 1 μm to about 3 μm. During the thinning process of substrate 1701, protection layer 218 can protect the low-k dielectric materials in front-side interconnect layer 101 from damage, the interconnect structures in front-side interconnect layer 101 from exposure, and substrate 102 from over-etch.

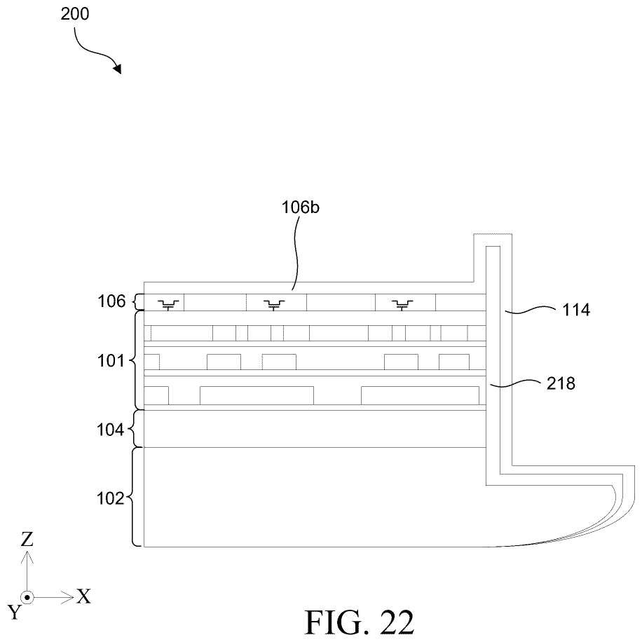

In operation 1650 of FIG. 16, an oxide layer is formed on the protection layer and the device layer. For example, as shown in FIG. 22, oxide layer 114 can be formed on protection layer 218 and device layer 106. In some embodiments, the processes in operation 1650 can be substantially the same as the process in operation 470 as shown in FIG. 4. In some embodiments, oxide layer 114 can be conformally deposited on protection layer 218 and device layer 106 by ALD, CVD, or other suitable deposition methods. In some embodiments, oxide layer 114 can include an oxide material, such as SiOₓ. In some embodiments, oxide layer 114 can include any suitable dielectric materials. In some embodiments, oxide layer 114 formed on protection layer 218 can further protect front-side interconnect layer 101 and device layer 106 and prevent water vapor absorption.

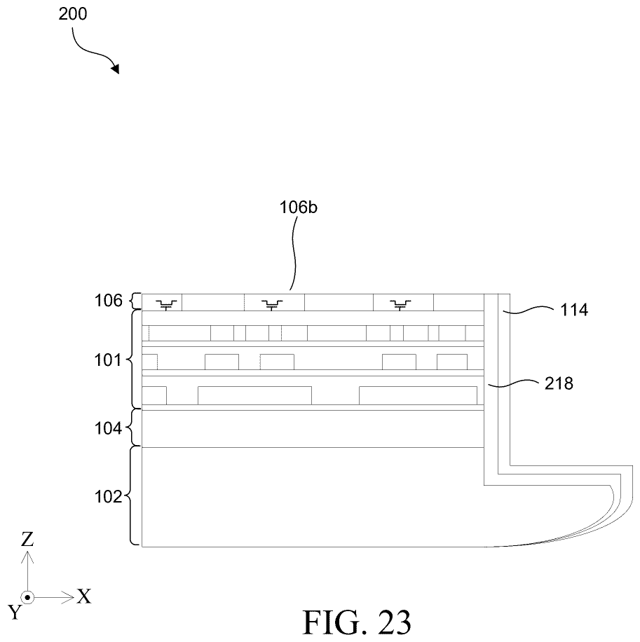

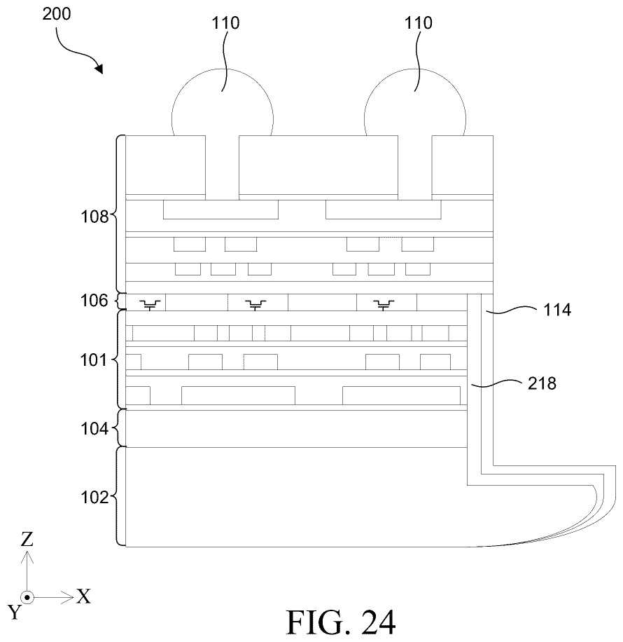

In operation 1660 of FIG. 16, top surfaces of the protection layer, the oxide layer, and the device layer are planarized. For example, as shown in FIG. 23, top surfaces of protection layer 218, oxide layer 114, and device layer 106 can be planarized. In some embodiments, a CMP process can planarize the top surfaces and remove the portion of protection layer 218 above backside 106b. The planarization of the top surfaces of protection layer 218, oxide layer 114, and device layer 106 can be followed by the formation of backside interconnect layer 108 and bump contacts 110, as shown in FIGS. 2 and 24. In some embodiments, backside interconnect layer 108 can include backside interconnects electrically connecting the one or more devices in device layer 106 to bump contacts 110 and external connections. In some embodiments, backside interconnect layer 108 can be formed by depositing one or more dielectric layers and forming the backside interconnects in the one or more dielectric layers. The backside interconnects can be connected to each other and the one or more devices in device layer 106. With protection layer 218, front-side interconnect layer 101 can be better protected from water vapor absorption, low-k dielectric materials in front-side interconnect layer 101 can be better protected from exposure, and thus edge defects can be reduced and damage to functional dies can be minimized.

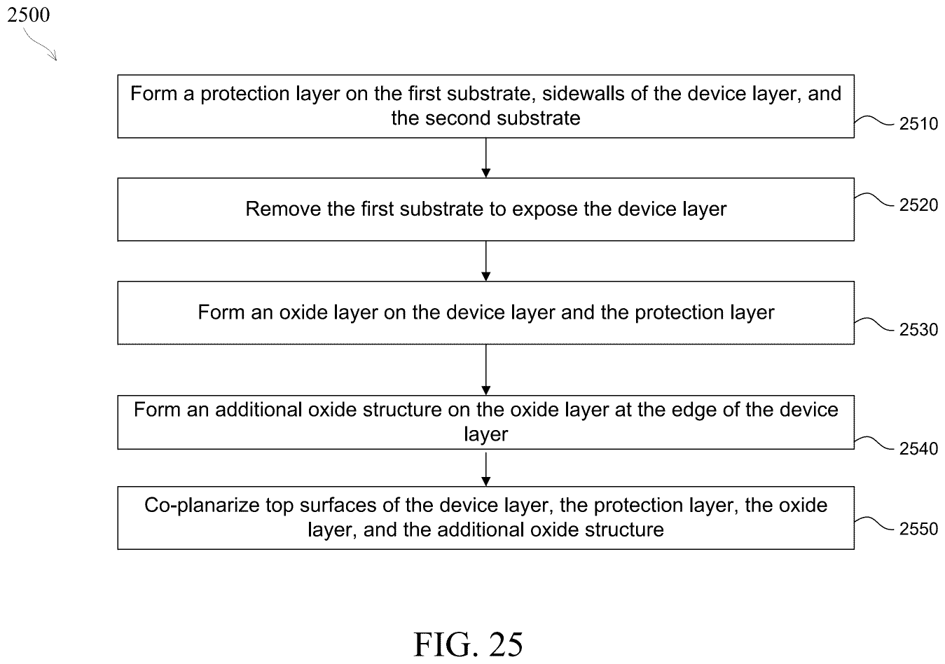

FIG. 25 is a flow diagram of a method 2500 for fabricating semiconductor device 300 having protection layer 218 and first and second oxide structures 112 and 116 at the wafer edge, in accordance with some embodiments. Method 2500 may not be limited to semiconductor device 300 and can be applicable to other devices that would benefit from the protection layer and oxide structures at the wafer edge. Additional fabrication operations may be performed between various operations of method 2500 and may be omitted merely for clarity and ease of description. Additional processes can be provided before, during, or after method 2500; one or more of these additional processes are briefly described herein. Moreover, not all operations may be needed to perform the disclosure provided herein. Additionally, some of the operations may be performed simultaneously or in a different order than shown in FIG. 25. In some embodiments, one or more other operations may be performed in addition to or in place of the presently-described operations.

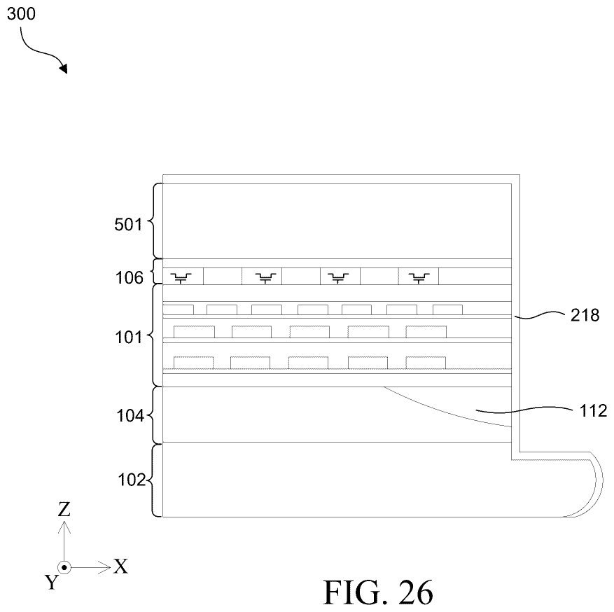

For illustrative purposes, the operations illustrated in FIG. 25 will be described with reference to the example fabrication process for semiconductor device 300 as illustrated in FIGS. 3 and 26-29. FIGS. 26-29 illustrate cross-sectional views of semiconductor device 300 at various stages of its fabrication process, in accordance with some embodiments. Elements in FIGS. 26-29 with the same annotations as elements in FIGS. 1-3 are described above. In some embodiments, method 2500 can build on semiconductor device 100 as shown in FIG. 11. Additional processes, such as operations 410-450 as shown in FIG. 4, can be performed before method 2500.

In referring to FIG. 25, method 2500 begins with operation 2510 and the process of forming a protection layer on the first substrate, sidewalls of the device layer and the first oxide structure, and the second substrate. For example, as shown in FIG. 26, protection layer 218 can be formed on substrate 501, sidewalls of device layer 106, front-side interconnect layer 101, and first oxide structure 112, and substrate 102. In some embodiments, the processes in operation 2510 can be substantially the same as the processes in operation 1630 as shown in FIG. 16. In some embodiments, as shown in FIG. 26, protection layer 218 can be conformally deposited on top surfaces of substrates 102 and 501 and sidewall surfaces of device layer 106, front-side interconnect layer 101, and first oxide structure 112 by ALD, CVD, or other suitable deposition methods. In some embodiments, protection layer 218 can include a protective material, such as Ti, TiN, SiC, SiCN, SiOₓ, SiNₓ, and other suitable protective materials. The protective material in protection layer 218 can have a high etch selectivity (e.g., from about 2 to about 50) with regard to the semiconductor material in substrate 501 (e.g., Si). The high etch selectivity of protection layer 218 can protect device layer 106, front-side interconnect layer 101, and first oxide structure 112 during the thinning process and subsequent backside processes. In some embodiments, protection layer 218 can prevent water vapor absorption of the low-k material in front-side interconnect layer 101. In some embodiments, protection layer 218 can prevent exposure of the interconnect structures in front-side interconnect layer 101 at the trim corner during the thinning process. In some embodiments, protection layer 218 can improve trim depth control and reduce edge defects generated during subsequent lithography and electroplating processes. After the deposition of protection layer 218, first oxide structure 112 can be enclosed by bonding layer 104, front-side interconnect layer 101, and protection layer 218.

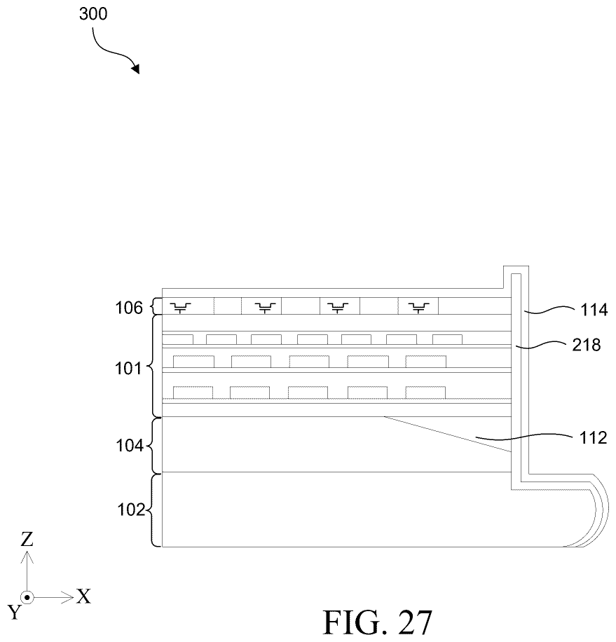

In operation 2520 of FIG. 25, the first substrate is removed to expose the device layer. For example, as shown in FIG. 27, substrate 501 can be removed to expose device layer 106. In some embodiments, the processes in operation 2520 can be substantially the same as the processes in operation 1640 as shown in FIG. 16. During the thinning process of substrate 501, protection layer 218 can protect the low-k dielectric materials in front-side interconnect layer 101 from damage, the interconnect structures in front-side interconnect layer 101 from exposure, and substrate 102 from over-etch.

In operation 2530 of FIG. 25, an oxide layer is formed on the protection layer and the device layer. For example, as shown in FIG. 27, oxide layer 114 can be formed on protection layer 218 and device layer 106. In some embodiments, the processes in operation 2530 can be substantially the same as the processes in operation 1650 as shown in FIG. 16. In some embodiments, oxide layer 114 formed on protection layer 218 can further protect front-side interconnect layer 101 and device layer 106 and prevent water vapor absorption.

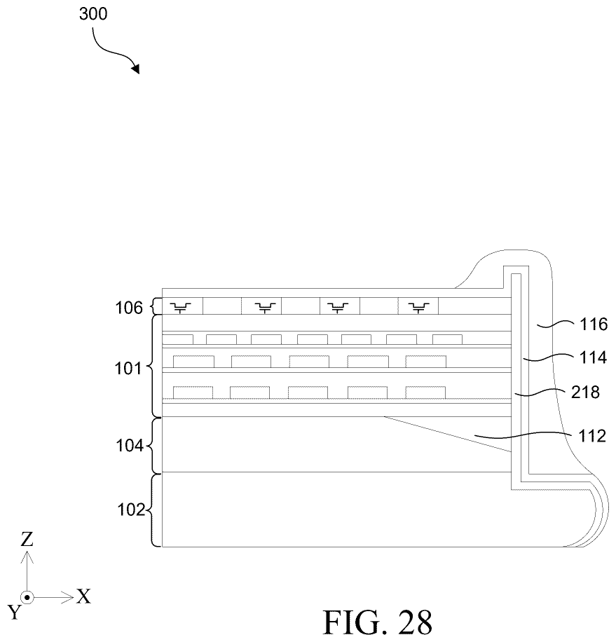

In operation 2540 of FIG. 25, an additional oxide structure can be formed on the oxide layer at the edge of the device layer. For example, as shown in FIG. 28, second oxide structure 116 can be formed on oxide layer 114 at the edge of device layer 106. In some embodiments, the processes in operation 2540 can be substantially the same as the processes in operation 480 as shown in FIG. 4. Second oxide structure 116 can be formed along sidewall surfaces of device layer 106, front-side interconnect layer 101, first oxide structure 112, and oxide layer 114. In some embodiments, second oxide structure 116 can protect oxide layer 114, front-side interconnect layer 101, and device layer 106 during subsequent backside processes.

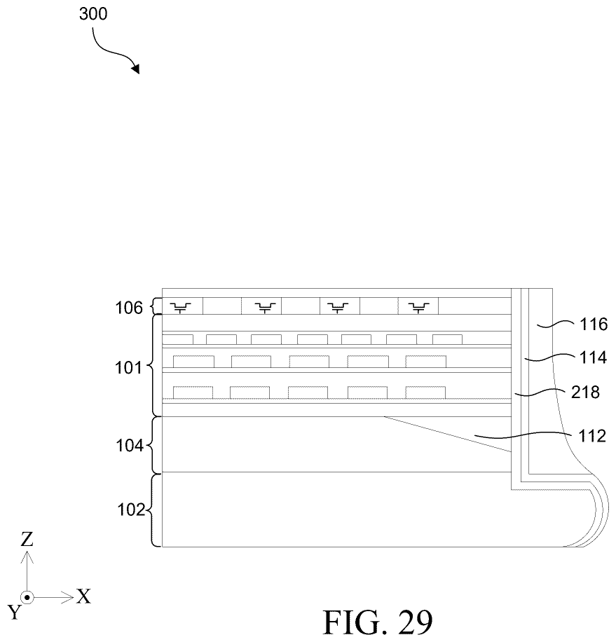

In operation 2550 of FIG. 25, top surfaces of the device layer, the protection layer, the oxide layer, and the additional oxide structure are planarized. For example, as shown in FIG. 29, top surfaces of device layer 106, protection layer 218, oxide layer 114, and second oxide structure 116 can be planarized. In some embodiments, the processes in operation 2550 can be substantially the same as the processes in operation 1660 as shown in FIG. 16. In some embodiments, a CMP process can planarize the top surfaces and remove the portion of protection layer 218 and second oxide structure 116 above backside 106b as shown in FIG. 28. The planarization of the top surfaces of device layer 106, protection layer 218, oxide layer 114, and second oxide structure 116 can be followed by the formation of backside interconnect layer 108 and bump contacts 110, as shown in FIG. 3. These fabrication operations are not described in details merely for ease of description.

Though the present disclosure describes forming semiconductor devices 100, 200, and 300 having protection layer 218 and first and second oxide structures 112 and 116 at the wafer edge, methods 400, 1600, and 2500 of forming protections layers at the wafer edge can be applied to other suitable structures and devices.

Various embodiments in the present disclosure provide example methods for forming semiconductor devices 100, 200, and 300 having protection layer 218 and first and second oxide structures 112 and 116 at the wafer edge. According to some embodiments, semiconductor devices 100, 200, and 300 can include bonding layer 104 to bond device layer 106 to substrate 102. Protection layer 218 in semiconductor devices 200 and 300 can be disposed on a top surface of the substrate 102 and sidewall surfaces of device layer 106. In some embodiments, protection layer 218 can include a high etch selectivity material to protect functional dies, dielectric materials, and interconnect structures at the wafer edge from damage during the substrate thinning process and subsequent backside process. In some embodiments, semiconductor devices 100 and 300 can include first and second oxide structures 112 and 116 on a top surface and along a sidewall surface of device layer 106. First and second oxide structures 112 and 116 can increase the distance between the trimmed wafer edge and the functional dies, thus reducing damage to the functional dies during the trimming process. In some embodiments, protection layer 218 and first and second oxide structures 112 and 116 can reduce the defects at the wafer edge by about 10% to about 50%.

In some embodiments, a method includes forming a device layer on a first substrate, forming an interconnect layer on the device layer, forming an oxide structure on a top surface and along a sidewall surface of the interconnect layer, forming a bonding layer on the oxide structure and the interconnect layer, and bonding the device layer to a second substrate with the bonding layer.

In some embodiments, a method includes forming a bonding layer on a first substrate. The first substrate includes a device layer and an interconnect layer on the device layer. The method further includes bonding the first substrate to a second substrate with the bonding layer, trimming edge portions of the first substrate, the device layer, and the interconnect layer, and forming a protection layer on the first substrate, the second substrate, and sidewalls of the device layer and the interconnect layer.

In some embodiments, a semiconductor structure includes a bonding layer on a substrate, an interconnect layer on the bonding layer, a device layer on the bonding layer and bonded to the substrate by the bonding layer, a protection layer disposed on a top surface of the substrate and a sidewall surface of the device layer and the interconnect layer, and an oxide layer disposed on the protection layer.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a device wafer comprising a device layer on a first substrate and an interconnect layer on the device layer;
forming an oxide structure on an edge region of the device wafer, wherein the oxide structure covers a top surface and a sidewall surface of the interconnect layer;
depositing a bonding layer on the oxide structure and the interconnect layer; and
bonding the device wafer to a second substrate with the bonding layer.

2. The method of claim 1, wherein forming the oxide structure comprises:
covering a center region of the device wafer with a plate; and
depositing an oxide material on the interconnect layer at the edge region of the device wafer.

3. The method of claim 1, further comprising vertically trimming the first substrate, the device layer, the interconnect layer, and the oxide structure at the edge region of the device wafer.

4. The method of claim 1, further comprising:
removing the first substrate to expose the device layer;
forming an oxide layer on the device layer, the interconnect layer, the oxide structure, and the second substrate; and
forming an additional oxide structure on the oxide layer at the edge region of the device wafer.

5. The method of claim 1, further comprising:
forming a protection layer on the first substrate, the second substrate, and sidewalls of the device layer, the oxide structure, and the interconnect layer;
removing the first substrate to expose the device layer; and
forming an oxide layer on the protection layer and the device layer.

6. The method of claim 5, further comprising co-planarizing top surfaces of the device layer, the protection layer, and the oxide layer.

7. The method of claim 5, further comprising:
forming an additional oxide structure on the oxide layer at the edge region of the device wafer, wherein the additional oxide structure is in contact with a sidewall surface of the oxide layer; and
co-planarizing top surfaces of the device layer, the protection layer, the oxide layer, and the additional oxide structure.

8. The method of claim 7, further comprising forming an additional interconnect layer on the top surfaces of the device layer, the protection layer, the oxide layer, and the additional oxide structure.

9. A method, comprising:
forming an oxide structure at an edge region of a first substrate, wherein the first substrate comprises a device layer and an interconnect layer on the device layer;
forming a bonding layer on the oxide structure and the interconnect layer;
bonding the first substrate to a second substrate with the bonding layer;
trimming the first substrate, the device layer, and the interconnect layer vertically at the edge region; and
forming a protection layer on the first substrate, the second substrate, and sidewalls of the device layer, the oxide structure, and the interconnect layer.

10. The method of claim 9, further comprising:
removing the first substrate to expose the device layer; and
forming an oxide layer on the protection layer and the device layer.

11. The method of claim 10, further comprising forming an additional oxide structure on the oxide layer adjacent to the sidewalls of the device layer, the oxide structure, and the interconnect layer.

12. The method of claim 11, wherein forming the additional oxide structure comprises:
covering a center region of the device layer with a plate; and
depositing an oxide material on the oxide layer adjacent to the sidewalls of the device layer, the oxide structure, and the interconnect layer.

13. The method of claim 11, further comprising co-planarizing top surfaces of the device layer, the protection layer, the oxide layer, and the additional oxide structure.

14. The method of claim 13, further comprising forming an additional interconnect layer on the top surfaces of the device layer, the protection layer, the oxide layer, and the additional oxide structure.

15. A semiconductor device, comprising:
a first interconnect layer on a substrate;
a device layer on the first interconnect layer;
an oxide layer on an edge portion of the substrate and sidewall surfaces of the device layer and the interconnect layer; and
a second interconnect layer on the device layer and the oxide layer.

16. The semiconductor device of claim 15, further comprising an oxide structure and a bonding layer between the first interconnected layer and the substrate, wherein the oxide structure is enclosed by the bonding layer, the interconnect layer, and the oxide layer.

17. The semiconductor device of claim 16, wherein the oxide structure comprises silicon oxide and is between edge portions of the bonding layer and the interconnect layer.

18. The semiconductor device of claim 15, further comprising a protection layer between the oxide layer and the sidewall surfaces of the device layer and the interconnect layer.

19. The semiconductor device of claim 15, further comprising an oxide structure disposed on a sidewall surface of the oxide layer and the edge portion of the substrate.

20. The semiconductor device of claim 15, wherein the interconnect layer comprises a low-k dielectric layer, and wherein the oxide layer covers sidewall surfaces of the low-k dielectric layer.
